(19) United States
(12) Patent Application Publication
(10) Pub. No.: US 2004/0188844 A1
(43) Pub. Date: Sep. 30, 2004

(54) Semiconductor device and pattern generating method

(75) Inventors: Masato Suga, Kawasaki (JP); Satoshi Otsuka, Kawasaki (JP)

Correspondence Address: STAAS & HALSEY LLP, SUITE 700, 1201 NEW YORK AVENUE, N.W., WASHINGTON, DC, 20005, US

(73) Assignee: FUJITSU LIMITED, Kawasaki (JP)

(21) Appl. No.: 10/786,026

(22) Filed: Feb. 26, 2004

(30) Foreign Application Priority Data
Mar. 28, 2003 (JP) 2003-091559

(51) Int. Cl. H01L 23/48

(52) U.S. Cl. 257/758

(57) ABSTRACT

A first dummy pattern is arranged in the region allowed to generate the first dummy pattern, after that, the second dummy pattern is generated in the region not allowed to generate the first dummy pattern but allowed to generate the second dummy pattern to thereby enable to arrange the dummy patterns in an efficient manner in the wiring layer, so that the wiring density can be improved and differences in the wiring densities can be reduced.

### CROSS-REFERENCE TO RELATED APPLICATIONS

This application is based upon and claims the benefit of priority from the prior Japanese Patent Application No. 2003-091559, filed on Mar. 28, 2003, the entire contents of which are incorporated herein by reference.

### BACKGROUND OF THE INVENTION

1. Field of the Invention

The present invention is related to a semiconductor device and a pattern generation method, and more particularly, to arrangement of a wiring pattern being a dummy in a semiconductor device having a multilayered wiring.

2. Description of the Related Art

In recent years, along with increasing density and advancing integration, in semiconductor devices, a multilayered wiring structure is being employed, where a wiring pattern (metal wiring pattern) is divided by an interlayer insulating film to be formed of a plurality of layers. With the adoption of the multilayered structure, wiring dimensions are substantially reduced to thereby prevent chip size from increasing and shorten the wiring length, so that delay in operation speed is restrained.

When fabricating a semiconductor device with a multilayered wiring, a process of CMP (Chemical Mechanical Polishing) is essential to diminish concavity and convexity generated by a wiring pattern on a lower wiring layer to thereby flatten a surface of the interlayer insulating film, the CMP process being a technique that polishes the interlayer insulating film and the wiring pattern so that level differences thereon are curbed. However, when there are large differences between wiring densities of (or a large distribution of wiring densities among) respective layers, step Height (erosion) or the like is caused to thereby bring trouble to the rest of the processes and resultant defective wiring pattern due to a disconnection or the like greatly affects the production yield of the wiring pattern.

As one solution to this problem, there has been a technique that generates the dummy pattern in a region having no wiring pattern (wiring data) after the layout designing thereof (see Japanese Patent Laid-Open No.Hei 5-343540 as an example). As mentioned above, with the dummy pattern generated, a minimum wiring density specified for the semiconductor device to be fabricated is ensured. This enables to reduce differences in the wiring densities in the semiconductor device so that improvement in flatness of the interlayer insulating film is attempted.

In the above-mentioned technique, in consideration of efficient generation of the dummy pattern and equalization of the wiring densities, on the same wiring layer, only such dummy patterns are generated that have the same shapes and sizes under the same arrangement rules. In addition, the dummy pattern here has the size and shape ensured of a certain width on the ground that substantial improvement in the wiring density cannot be attained in the case of the dummy pattern with a critical fine width acceptable in the semiconductor device. Therefore, in the prior art, there is such a problem that the spaces between the wiring patterns for generating the dummy pattern tend to be increased.

FIG. 6 is a flow chart showing the dummy pattern generation method of the prior art. In FIG. 6, the dummy pattern generation method is presented by citing a case on any one wiring layer out of a plurality of wiring layers in the multilayered wiring of the LSI.

A layout data (a design data for the LSI, for example, GDS data and so forth) which has completed an ordinary course of layout designing is inputted (Step S71). The dummy pattern is generated within a generation region line whether or not the wiring pattern exists (Step S72). The generation region line is a periphery of a region within a chip, the region being previously defined for generating the dummy pattern and being other than an outer edge portion of the chip.

Next, the dummy pattern arranged in step S72 is judged whether or not it meets the arrangement rules (Step S73), so that the dummy pattern against the rule is removed from the layout data (Step S74). The arrangement rules include the rules on the distances to/from the wiring pattern, the other dummy pattern, and a pad region; conditions on the border of the generation region; and so forth. In this manner, the layout data having the dummy pattern arranged and meeting the arrangement rules is obtained. With the layout data, a mask data is created (Step S75).

An example arrangement of the dummy patterns by the above-described method in the prior art for generating the dummy pattern is shown in FIG. 7. In FIG. 7, WP71 and WP72 denote the wiring patterns (actual patterns) and DP71 denotes a dummy pattern.

### SUMMARY OF THE INVENTION

An object of the present invention is to improve a minimum wiring density in a semiconductor device by efficiently arranging a dummy pattern.

The semiconductor device of the present invention has an actual pattern and plural types of dummy patterns on a wiring layer thereof, in which the dummy patterns have at least either a different size or a different shape from each other for each type.

Further, in a pattern generation method of the present invention, a first dummy pattern arrangement step including arranging first dummy patterns by generating the first dummy patterns in a region allowed to generate the first dummy pattern based on a layout data having actual patterns arranged on a wiring layer in the semiconductor device, and a repeat step including repeating a kth dummy pattern arrangement step by incrementally changing a value of k, the kth dummy pattern arrangement step including arranging kth dummy patterns by generating kth dummy patterns being different from the first to a (k−1) th (k is a natural number from 2 to N, N is optional.) dummy patterns in a region allowed to generate the kth dummy patterns based on the layout data having actual patterns and the first to the (k−1) th dummy patterns arranged on the wiring layer.

### BRIEF DESCRIPTION OF THE DRAWINGS

FIG. 1 is a flow chart showing a two-step dummy pattern generation method of the present embodiment;

FIG. 2 is a view showing an example arrangement of the present embodiment;

FIG. 3 is a view showing another example arrangement of the present embodiment;

FIGS. 4A, 4B and 4C are explanatory views showing a resultant arrangement of the dummy patterns of the present embodiment;

FIG. 5 is a flow chart showing a multi-step pattern generation method of the present embodiment;

FIG. 6 is a flow chart showing a dummy pattern generation method of the prior art;

FIG. 7 is a view showing an example arrangement of the dummy patterns of the prior art; and

FIG. 8 is a flow chart showing a dummy pattern generation method in which the dummy pattern is arranged by rotating 0 (zero) degrees and 90 degrees.

### DETAILED DESCRIPTION OF THE PREFERRED EMBODIMENTS

In the above-described prior art, there occurs no problem in the case of the region having no wiring pattern after the layout designing, since the wiring density thereof is that previously ensured by the dummy pattern. However, in the case of the region between such wiring patterns that arranged without having the space for arranging the dummy pattern, any dummy pattern cannot be arranged therein. Therefore, the wiring density of the region is ensured only by the wiring pattern, exhibiting a tendency to widen the differences in the wiring densities. Along with the advance in miniaturization in the rules on the semiconductor device, the wiring pattern is made shrink, while the width of the dummy pattern cannot be reduced to ensure the wiring density, so that the differences in the wiring densities tends to be widened further.

Hereinafter, an embodiment of the present invention will be described with reference to the accompanying drawings. The present embodiment to be described below shows, as one example, a random wiring layer of a plurality of wiring layers in a semiconductor device of a multilayered structure such as an LSI and so forth.

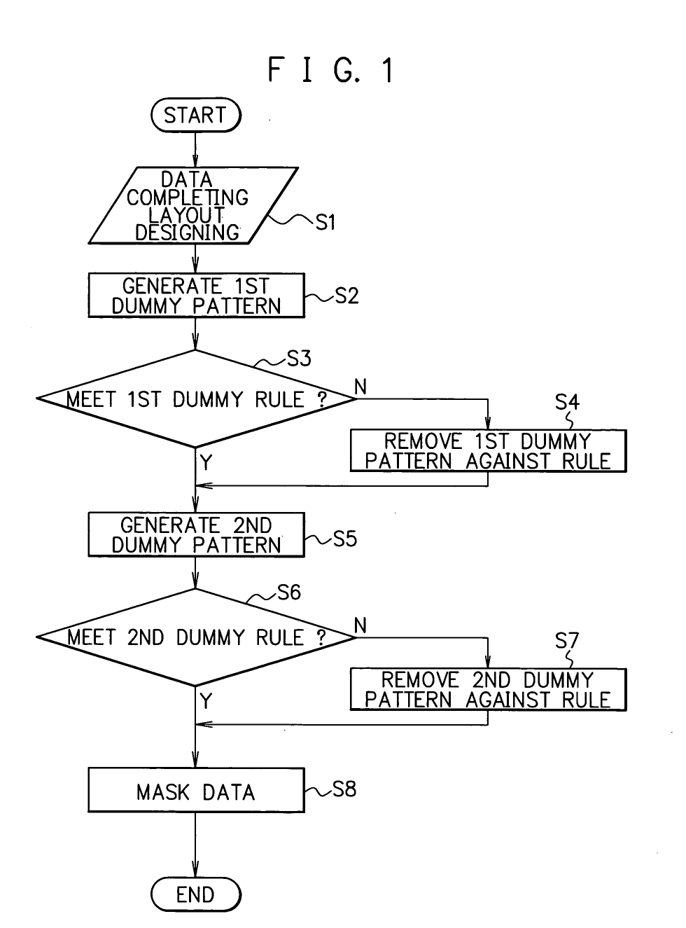

FIG. 1 is a flow chart showing a two-step dummy pattern generation method according to the embodiment of the present invention.

In step S1, a layout data (a design data for the LSI, for example, GDS data and so forth) which has completed an ordinary course of layout designing is provided. In step S2, a first dummy pattern having a given shape and size is generated across the board within a generation region line without regard to the presence of a wiring pattern. Here, the generation region line is a periphery of a region within a chip, the region being previously defined for generating the dummy pattern and being other than an outer edge portion of the chip.

Next, in step S3, it is judged whether or not the first dummy pattern arranged in step S2 meets first arrangement rules. As a result of the above judgment, when there is the first dummy pattern against the first arrangement rules, the first dummy pattern against the first arrangement rules is removed from the layout data, in step S4.

Here, the first arrangement rules includes space (distance) to/from the wiring pattern, distance to/from the first dummy pattern, distance to/from a pad region, conditions on the border of the generation region and so forth.

In this manner, such layout data can be obtained as having the first dummy pattern arranged only in the region of the chip where the first dummy pattern is allowed to be generated (hereinafter referred to as “generable region”).

Next, in step S5, with the layout data having the first dummy pattern arranged in a manner as mentioned above, second dummy pattern is generated across the board within the generation region line without regard to the presence of the wiring pattern and the first dummy pattern. The second dummy pattern has, at least, different shape or different size from that of the first dummy pattern.

In step S6, it is judged whether or not the second dummy pattern generated in step S5 meets a second arrangement rules. As a result of the above judgment, when there is the second dummy pattern against the second arrangement rules, the second dummy pattern against the second arrangement rules is removed from the layout data, in step S7. Here, the second arrangement rules provide relation with the first dummy pattern in addition to the above-mentioned first arrangement rules. For example, the distance to/from the first dummy pattern is included into the second arrangement rules.

In this manner, such layout data can be obtained as having the second dummy pattern arranged only in the generable region of the second dummy pattern while in a state still maintaining the first dummy pattern arranged.

In step S8, based on the layout data obtained in the above-described manner and having the first and the second dummy patterns arranged respectively meeting the first and the second arrangement rules, a mask data is created. With a mask created from the mask data, the semiconductor device such as the LSI and the like in which the first dummy pattern and the second dummy pattern are appropriately arranged on each wiring layer is fabricated.

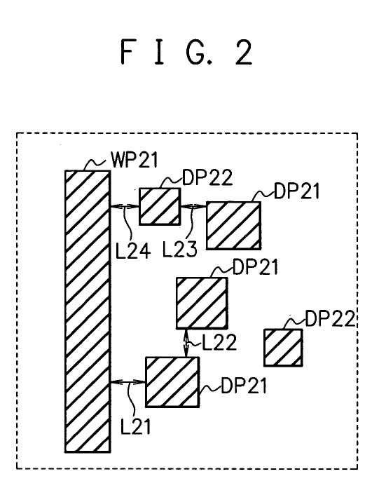

FIG. 2 is a view showing an example arrangement of the first and the second dummy patterns by the above-described two-step dummy pattern generation method.

In FIG. 2, WP21 denotes the wiring pattern (actual pattern), DP21 denotes the first dummy pattern, and DP22 denotes the second dummy pattern. The first and the second dummy patterns DP21 and DP22 respectively have the same square shapes. In terms of the size (dimensions), the second dummy pattern DP22 is smaller than the first dummy pattern DP21.

The first dummy pattern DP21 is arranged so that the first arrangement rules on a distance L21 to/from the nearest wiring pattern WP21, a distance L22 to/from the other nearest first dummy pattern DP21, and the like are met. In addition, the second dummy pattern DP22 being smaller than the first dummy pattern DP21 is arranged so that the second arrangement rules on a distance L24 to/from the nearest wiring pattern WP21, a distance L23 to/from the nearest first dummy pattern DP21, and the like are met.

As shown in FIG. 2, making the second dummy pattern DP22 smaller than the first dummy pattern DP21 still allows the second dummy pattern DP22 to be arranged even in the region where the first dummy pattern DP21 is impossible to be generated.

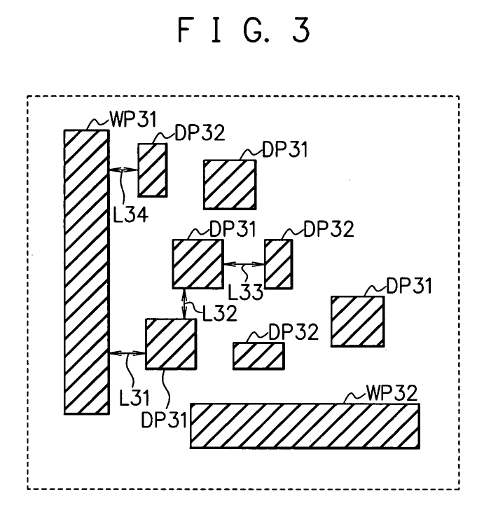

FIG. 3 is a view showing the other example arrangement of the first and the second dummy patterns by the two-step dummy pattern generation method mentioned before.

Commonly, the first dummy pattern frequently has the square shape with the intention to increase the density of the dummy pattern itself and to improve efficiency in generation. Meanwhile, when the second dummy pattern is shaped in the same but smaller square than the first dummy pattern, there arises a problem such as of lowering the density of the dummy pattern itself or the efficiency in generation.

The example shown in FIG. 3 is a case where the second dummy pattern has one rectangular shape in view of the above-mentioned considerations.

In FIG. 3, WP31 and WP32 denote wiring patterns (actual patterns), DP31 denotes the first dummy pattern, and DP32 denotes the second dummy pattern. The first dummy pattern DP31 has the square shape and the second dummy pattern DP32 has the rectangular shape formed by shortening a pair of facing sides of the first dummy pattern DP31.

Additionally, the second dummy pattern DP32 is smaller than the first dummy pattern DP31 in size (dimensions). For confirmation, in FIG. 3, even though the long side of the second dummy pattern DP32 and one side of the first dummy pattern DP31 both have the same length, the long side of the second dummy pattern DP32 may have any length as long as the second dummy pattern DP32 is smaller than the first dummy pattern DP31.

The first dummy pattern DP31 is arranged so that it meets the first arrangement rules on a distance L31 to/from the nearest wiring pattern WP31, a distance L32 to/from the nearest first dummy pattern DP31, and the like. In addition, the second dummy pattern DP32 being smaller than the first dummy pattern DP31 is arranged so that it meets the second arrangement rules on a distance L34 to/from the nearest wiring pattern WP31, a distance L33 to/from the nearest first dummy pattern DP31 and the like.

Here, the second dummy pattern DP32 may be arranged by rotating an angle of 90 degrees while having the long sides thereof in both directions of X and Y.

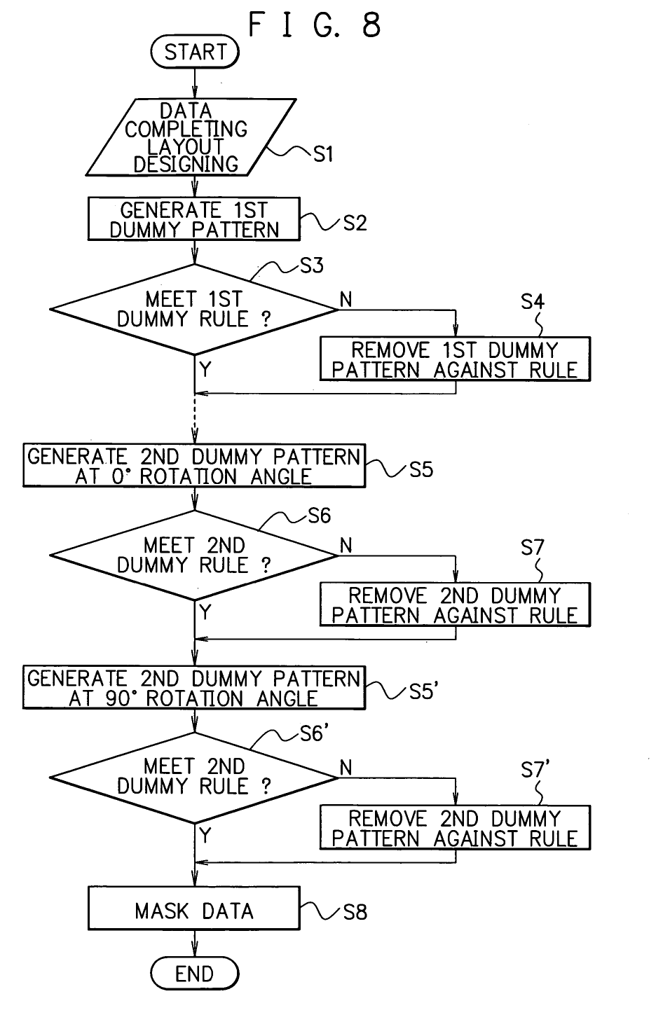

FIG. 8 is a flow chart showing the dummy pattern generation method in the case where the second dummy patterns DP32 are arranged by rotating 0 (zero) degrees and 90 degrees.

In FIG. 8, steps S1 to S7 and step S8 are the same as the corresponding steps of the flow chart shown in FIG. 1 except that, in step 5 in FIG. 8, the second dummy pattern is arranged by rotating 0 (zero) degrees.

In step S5′ following the operation of step 6 or step S7, with the layout data having the second dummy pattern arranged by rotating 0 (zero) degrees, the second dummy pattern rotated 90 degrees is generated in the generation region line without regard to the presence of the wiring layer, the first dummy pattern, and the second dummy pattern with the rotation angle of 0 (zero) degrees.

Next, in step S6′ and step S7′, similarly to step S6 and step S7, it is judged whether or not the second dummy patterns arranged in step 5′ by rotating 90 degrees meet the second arrangement rules, so that, based on the judgment result, the second dummy pattern rotated 90 degrees and against the second arrangement rules is removed from the layout data to thereby go to step S8.

Note that, in FIG. 8, after arranging the second dummy pattern by rotating 0 (zero) degrees, the other second dummy pattern is arranged by rotating 90 degrees, yet, the other second dummy pattern rotated 90 degrees may be arranged before arranging the second dummy pattern with the rotation angle of 0 (zero) degrees.

Still, for instance, for arranging the second dummy pattern at any rotation angle while changing the rotation angle, what have to be done is to generate the second dummy pattern by rotating a given angle in step 5′ in FIG. 8 and carry out step S5′ to S7′ repeatedly (by looping) up to obtain the required angle. For example, when the number of the rotation angles other than 0 (zero) degrees is x, what have to be done is to carry out step S5′ though S7′ repeatedly x-times by sequentially changing the angle.

As shown in FIG. 3, making the second dummy pattern DP32 smaller than the first dummy pattern DP31 and making the same into the rectangular shape allows the second dummy pattern DP32 to be arranged even in the region where the first dummy pattern DP31 is impossible to be generated. For example, when the short sides of the rectangular-shaped dummy pattern are miniaturized to a degree of minimum standard in the semiconductor device, such a probability is increased as generating the dummy pattern in the region between the wiring pattern and the first dummy pattern, and between the wiring patterns. Specifically, efficiency in generation is whereby improved.

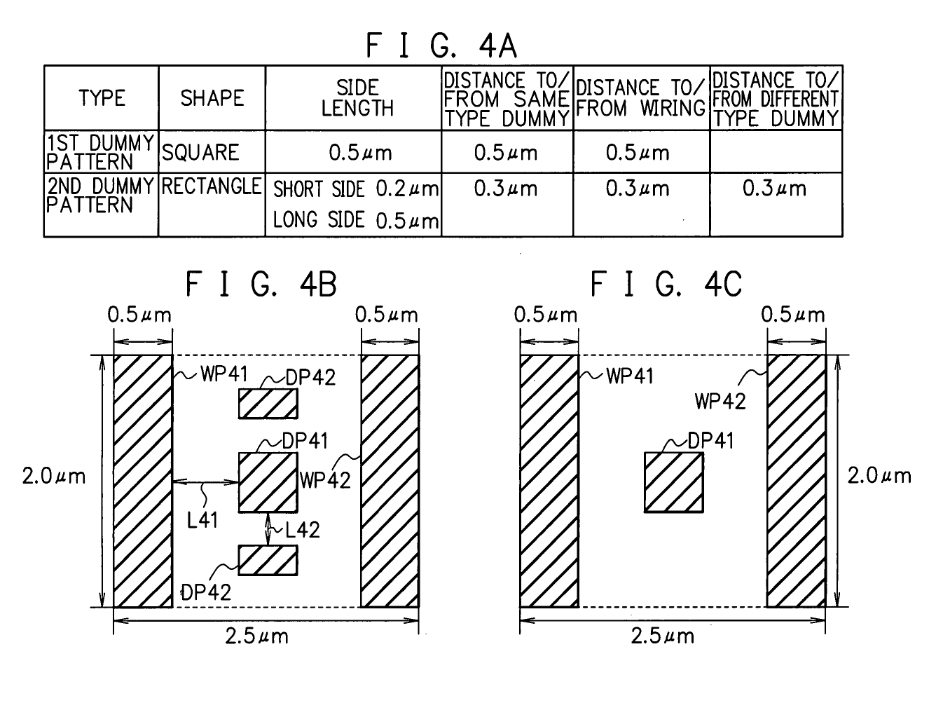

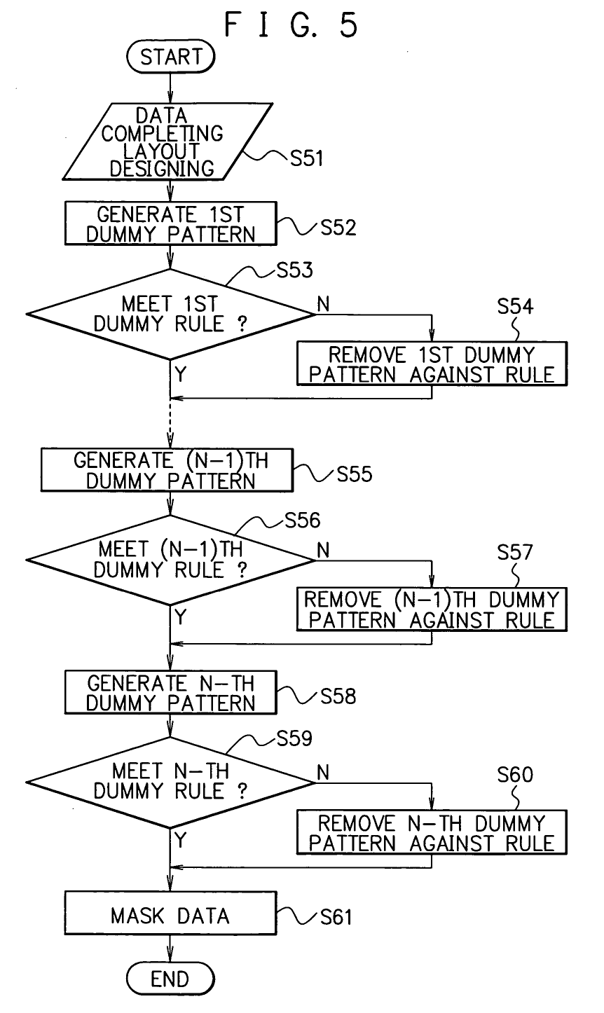

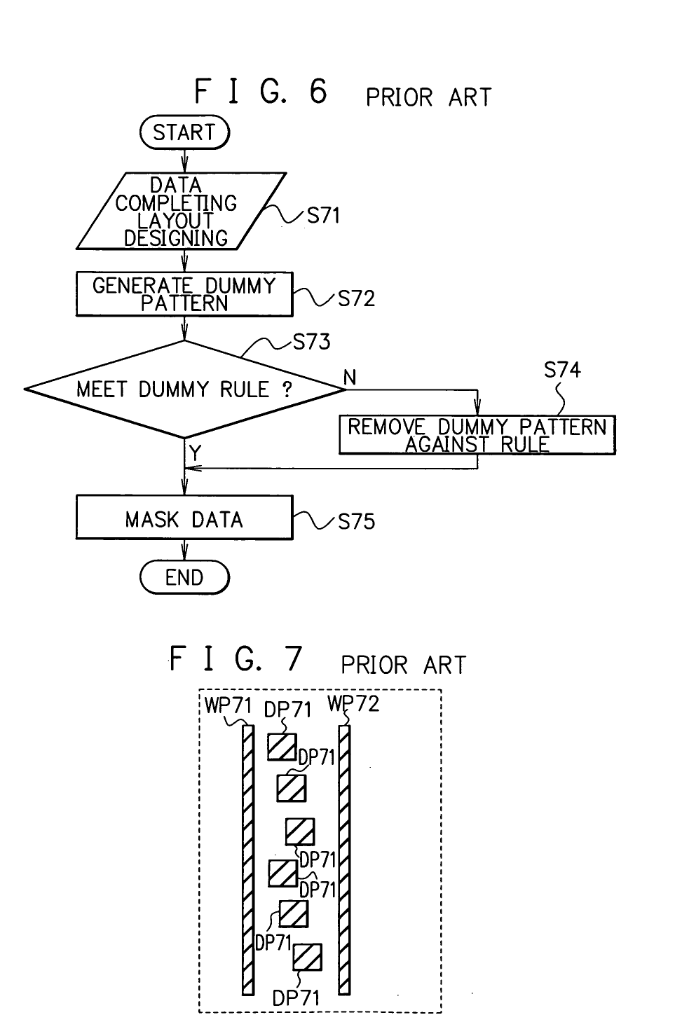

Hereinbelow, based on FIGS. 4A to 4C, the resultant arrangement of the dummy patterns by the dummy pattern generation method of the present embodiment will be described by comparison with that of the prior art.

FIG. 4A is a table showing an example specification of the dummy pattern to be generated by the dummy pattern generation method of the present embodiment. The table specifies that the first dummy pattern has a square shape with one side being 0.5 μm in length, and also specifies as the first arrangement rules that the distance (0.5 μm) to/from the other first dummy pattern and the distance (0.5 μm) to/from the wiring pattern.

Also, it is specified therein that the second dummy pattern has a rectangular shape with the short sides and long sides thereof being 0.2 μm and 0.5 μm respectively in length and that, as the second arrangement rules, the distance (0.3 μm) to/from the other second dummy pattern, the distance (0.3 μm) to/from the wiring pattern, and the distance (0.3 μm) to/from the first dummy pattern.

Note that there is indicated no condition on the border in the arrangement rules on the generation region, the dummy pattern over the border line of the generation region is deemed to be against the rules.

FIGS. 4B and 4C are views showing the example arrangements of the dummy patterns generated and arranged by the dummy pattern generation method of the present embodiment and by the prior art respectively. As an example, there is provided the generation region of 2.5 μm×2.0 μm having at both ends thereof wiring patterns WP41 and WP42, respective one sides thereof being 0.5 μm in length.

As shown in FIG. 4B, according to the dummy pattern generation method of the present embodiment, with the first dummy pattern and the second dummy pattern respectively arranged, the wiring density ends up 49%, while in the case of the prior art where only the first dummy pattern DP41 is arranged, as shown in FIG. 4C, the wiring density ends in 45%. For reference, the above is just one example and the effect will further increase in the case where the distance between the wiring patterns is shortened or the like.

As has been elaborated in the above, according to the present embodiment, after arranging the first dummy pattern in the generable region of the same, namely the region meeting the first arrangement rules, it is impossible to arrange the first dummy pattern, however, the second dummy pattern is generated instead in the generable region of the same, namely the region meeting the second arrangement rules. This makes it possible to improve the wiring density by efficiently arranging the dummy pattern in the wiring layer, and to reduce differences between wiring densities (narrow distribution of wiring densities). As a result, flatness of an interlayer insulating film of a multilayered wiring is improved to thereby reliability and production yield of the semiconductor device such as of the LSI and so forth can be improved.

Note that, in the above embodiment the two-step dummy pattern generation method is described as one example, however, the present invention is not limited thereto and whereby the dummy pattern can be generated by any plural steps as shown in FIG. 5.

FIG. 5 is a flow chart showing a multi-step dummy pattern generation method in which the steps is extended up to N steps (N is a natural number equals to two or more).

Basic process is similar to that of the two-step dummy pattern generation method shown in FIG. 1 above, with the layout data having dummy patterns arranged on a (k−1) th wiring layer (k=2 to N), a kth dummy pattern is generated across the board within the generation region line (step S52, S55, S58). Steps of excluding the dummy pattern being against the kth arrangement rules from the layout data (step S54, S57, S59) are carried out repeatedly. Each of the dummy patterns on the first to the Nth wiring layers has such a shape and a size as at least one of which is different from each other. For example, the sizes of the dummy patterns are gradually decreased.

Also, in the method described above, it is possible to reduce differences in wiring densities by efficiently arranging the dummy pattern in the wiring layer similarly to the case of the above-described two-step dummy pattern generation method. This makes it possible to improve flatness of the interlayer insulating film in the multi-layered wiring and reliability and production yield of the semiconductor device such as of the LSI and so forth.

Still, in the above embodiment, the dummy patterns are generated across the board within the generation region line to remove thereafter the dummy pattern against the arrangement rules with the purpose to save processing time, whereas it is also possible to make the judgment related to the arrangement rules before generating the dummy pattern so that the dummy pattern is generated only in the position meeting the arrangement rules.

In the above embodiment, further, the dummy patterns are arranged in the direction of either X or Y, yet, the dummy patterns may be arranged by rotating any angle. Furthermore, the sizes of the dummy patterns are gradually decreased, yet, the same effect can also be obtained only by differentiating the shapes. Specifically, the dummy pattern having the same dimension and smaller short sides can bring about the same effect.

As has been described hereinbefore, according to the present invention, even when it is impossible to generate one dummy pattern in the wiring layer of the semiconductor device, the other different dummy pattern can be generated to thereby enable to efficiently arranging the dummy patterns, so that minimum wiring density can be increased. Therefore, differences in wiring densities in the wiring layer can be decreased to thereby improve the flatness of the interlayer insulating film, so that improvement in reliability and production yield can be attained.

The present embodiment is to be considered in all respects as illustrative and no restrictive, and all changes which come within the meaning and range of equivalency of the claims are therefore intended to be embraced therein. The invention may be embodied in other specific forms without departing from the spirit or essential characteristics thereof.

What is claimed is:

1. A semiconductor device having an actual pattern and plural types of dummy patterns on a wiring layer thereof,
wherein said plural types of dummy patterns on the wiring layer have at least either of a different size or a different shape from each other for the type of said dummy pattern.

2. The semiconductor device according to claim 1,
wherein said dummy patterns are different in size for each type.

3. The semiconductor device according to claim 1,
wherein said dummy patterns have rectangular shapes with same longer sides and different shorter sides in length, the shorter sides being different from each other for each type.

4. A semiconductor device having an actual pattern, a first dummy pattern, and a second dummy pattern on a wiring layer thereof,
wherein said second dummy pattern has at least either of a different shape or a different size from corresponding that of the first dummy pattern.

5. The semiconductor device according to claim 4,
wherein said second dummy pattern is smaller than said first dummy pattern.

6. The semiconductor device according to claim 5,
wherein said second dummy pattern has a rectangular shape.

7. The semiconductor device according to claim 5,
wherein said first dummy pattern has a square shape and said second dummy pattern has a rectangular shape with same longer sides in length as one side of said first dummy pattern and shorter sides which are shorter than said one side.

8. A pattern generation method comprising:
a first dummy pattern arrangement step including arranging first dummy patterns by generating the first dummy patterns in a region allowed to generate the first dummy pattern based on a layout data having actual patterns arranged on a wiring layer in a semiconductor device; and
a repeated step including repeating a kth dummy pattern arrangement step by incrementally changing a value of k, said kth dummy pattern arrangement step including arranging kth dummy patterns by generating the kth dummy patterns being different from the first to the (k−1)th (k is a natural number from 2 to N, N is optional.) dummy patterns in a region allowed to generate the kth dummy pattern based on the layout data having actual patterns and the first to the (k−1)th dummy patterns arranged on the wiring layer.

9. The pattern generation method according to claim 8,
wherein the first dummy pattern is a biggest in size and the kth dummy patterns have sizes which are decrementally changed along with the values of the k which are incrementally changed.

10. The pattern generation method according to claim 9,
wherein the first to the kth dummy patterns have rectangular shapes.

11. The pattern generation method according to claim 10,
wherein the first to the kth dummy patterns have same longer sides in length with each other.

12. The pattern generation method according to claim 8,
wherein each dummy pattern is arranged by rotating a corresponding angle when arranging the kth dummy pattern in the kth dummy pattern arrangement step.

13. The pattern generation method according to claim 8, wherein the first dummy pattern arrangement step comprises:
generating the dummy pattern,
judging whether or not the dummy pattern generated meets an arrangement rule; and
excluding the dummy pattern not meeting the arrangement rule, based on the judgment result.

14. A pattern generation method comprising:
a first dummy pattern arrangement step including arranging first dummy patterns by generating the first dummy patterns in a region allowed to generate the first dummy pattern, based on a layout data having an actual pattern arranged on a wiring layer in a semiconductor device; and
a second dummy pattern arrangement step including arranging second dummy patterns by generating the second dummy patterns in a region allowed to generate the second dummy pattern based on the layout data having the actual pattern and the first dummy pattern arranged on the wiring layer, the second dummy pattern being a dummy pattern different from the first dummy pattern.

15. The pattern generation method according to claim 12,
wherein the value of the k is 2 and, in the second dummy pattern arrangement step, the second dummy pattern is arranged by rotating an angle of 0 (zero) degrees, and after that, based on a layout data having the actual pattern, the first dummy pattern, and the second dummy pattern rotated the angle of 0 (zero) degrees, which are arranged in the wiring layer, the second dummy pattern is generated and arranged by rotating the angle of no more than 90 degrees in the region allowed to generate the second dummy pattern.
